(19) United States
(12) Patent Application Publication
(10) Pub. No.: US 2005/0219913 A1
(43) Pub. Date: Oct. 6, 2005

(54) Non-volatile memory array

(75) Inventors: Kyu Hyun Choi, Cupertino, CA (US); Sheau-suey Li, Cupertino, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: O2IC, Inc., Cupertino, CA (US)

(21) Appl. No.: 10/819,669

(22) Filed: Apr. 6, 2004

(51) Int. Cl. G11C 16/06

(52) U.S. Cl. 365/185.29; 365/185.18

(57) ABSTRACT

Each non-volatile memory cell of an array of includes a guiding gate extending along a first portion of the cell's channel and a control gate extending along a second portion of the cell's channel. The first and second portions of the channel do not overlap. The guiding gate, which overlays the substrate above the channel, is insulated from the substrate via an oxide layer. The control gate, which also overlays the substrate above the channel region, is insulated from the substrate via an oxide-nitride-oxide layer. Each row of the array has a first terminal coupled to the guiding gates, and a second terminal coupled to the control gates of the cells disposed in that row. Each column of the array has a first terminal coupled to the drain regions, and a second terminal coupled to the source regions of the cells disposed in that column.

### CROSS-REFERENCES TO RELATED APPLICATIONS

The present application is related to U.S. application Ser. No. 10/394,417 filed on Mar. 19, 2003, Attorney Docket No. 021801-2.10US, entitled “Non-Volatile Memory Device” the content of which is incorporated herein by reference in its entirety.

### BACKGROUND OF THE INVENTION

The present invention relates to semiconductor integrated circuits. More particularly, the invention provides a semiconductor memory array that has integrated non-volatile and dynamic random access memory cells. Although the invention has been applied to a single integrated circuit device in a memory application, there can be other alternatives, variations, and modifications. For example, the invention can be applied to embedded memory applications, including those with logic or micro circuits, and the like.

Semiconductor memory devices have been widely used in electronic systems to store data. There are generally two types of memories, including non-volatile and volatile memories. The volatile memory, such as a Static Random Access Memory (SRAM) or a Dynamic Random Access Memory (DRAM), loses its stored data if the power applied has been turned off. SRAMs and DRAMs often include a multitude of memory cells disposed in a two dimensional array. Due to its larger memory cell size, an SRAM is typically more expensive to manufacture than a DRAM. An SRAM typically, however, has a smaller read access time and a lower power consumption than a DRAM. Therefore, where fast access to data or low power is needed, SRAMs are often used to store the data.

Non-volatile semiconductor memory devices are also well known. A non-volatile semiconductor memory device, such as flash Erasable Programmable Read Only Memory (Flash EPROM), Electrically Erasable Programmable Read Only Memory (EEPROM) or, Metal Nitride Oxide Semiconductor (MNOS), retains its charge even after the power applied thereto is turned off. Therefore, where loss of data due to power failure or termination is unacceptable, a non-volatile memory is used to store the data.

Unfortunately, the non-volatile semiconductor memory is typically slower to operate than a volatile memory. Therefore, where fast store and retrieval of data is required, the non-volatile memory is not typically used. Furthermore, the non-volatile memory often requires a high voltage, e.g., 12 volts, to program or erase. Such high voltages may cause a number of disadvantages. The high voltage increases the power consumption and thus shortens the lifetime of the battery powering the memory. The high voltage may degrade the ability of the memory to retain its charges due to hot-electron injection. The high voltage may cause the memory cells to be over-erased during erase cycles. Cell over-erase results in faulty readout of data stored in the memory cells.

The growth in demand for battery-operated portable electronic devices, such as cellular phones or personal organizers, has brought to the fore the need to dispose both volatile as well as non-volatile memories within the same portable device. When disposed in the same electronic device, the volatile memory is typically loaded with data during a configuration cycle. The volatile memory thus provides fast access to the stored data. To prevent loss of data in the event of a power failure, data stored in the volatile memory is often also loaded into the non-volatile memory either during the configuration cycle, or while the power failure is in progress. After power is restored, data stored in the non-volatile memory is read and stored in the non-volatile memory for future access. Unfortunately, most of the portable electronic devices may still require at least two devices, including the non-volatile and volatile, to carry out backup operations. Two devices are often required since each of the devices often rely on different process technologies, which are often incompatible with each other.

To increase the battery life and reduce associated costs, in accordance with one known method, a non-volatile memory array and a volatile memory array are integrated on the same chip. The non-volatile and volatile memory arrays communicate with one another via an interface. In accordance other methods, non-volatile SRAMs and non-volatile DRAMs have been developed. Such devices have the non-volatile characteristics of non-volatile memories, i.e., retain their charge during a power-off cycle, but provide the relatively fast access times of the volatile memories. As merely an example, FIG. 1 is a transistor schematic diagram of a prior art non-volatile DRAM 10. Non-volatile DRAM 10 includes transistors 12, 14, 16 and EEPROM cell 18. The control gate and the drain of EEPROM cell 18 form the DRAM capacitor. Transistors 12 and 14 are the DRAM transistors. Transistor 16 is the mode selection transistor and thus selects between the EEPROM and the DRAM mode.

FIG. 2 is a transistor schematic diagram of a prior art non-volatile SRAM 40. Non-volatile SRAM 40 includes transistors 42, 44, 46, 48, 50, 52, 54, 56, resistors 58, 60 and EEPROM memory cells 62, 64. Transistors 48, 50, 52, 54 and resistors 58, 60 form a static RAM cell. Transistors 42, 44, 46, 56 are select transistors coupling EEPROM memory cells 62 and 64 to the supply voltage Vcc and the static RAM cell. Transistors 48 and 54 couple the SRAM memory cell to the true and complement bitlines BL and \overline{BL}. EEPROM 18 of non-volatile DRAM cell 10 (FIG. 1) and EEPROM 62, 64 of non-volatile SRAM cell 40 (FIG. 2) consume relatively large amount of current and thus shorten the battery life.

A need continues to exist for a memory array formed using relatively small non-volatile memory devices that, among other things, consume less power than those known in the prior art. While the invention is described in conjunction with the preferred embodiments, this description is not intended in any way as a limitation to the scope of the invention. Modifications, changes, and variations, which are apparent to those skilled in the art can be made in the arrangement, operation and details of construction of the invention disclosed herein without departing from the spirit and scope of the invention.

### BRIEF SUMMARY OF THE INVENTION

A non-volatile memory array, in accordance with the present invention, includes, in part, an NxM non-volatile memory devices disposed in N rows and M columns of the array. Each non-volatile memory device further includes, in part, a guiding gate that extends along a first portion of the device's channel length and a control gate that extends along a second portion of the device's channel length. The first and second portions of the channel length do not overlap. The guiding gate, which overlays the substrate above the channel region, is insulated from the semiconductor substrate in which the device is formed via an oxide layer. The control gate, which also overlays the substrate above the channel region, is insulated from the substrate via an oxide-nitride-oxide layer. Each row of the array has a first associated terminal coupled to the guiding gates of the non-volatile memory devices disposed in that row, and a second associated terminal coupled to the control gates of the non-volatile memory devices disposed in that row. Moreover, each column of the array has a first associated terminal coupled to the drain regions of the non-volatile memory devices disposed in that column, and a second associated terminal coupled to the source regions of the non-volatile memory devices disposed in that column.

To erase a block of the memory array using tunneling, a relatively high negative voltage, in the range of, e.g., −5 volts to −14 volts, is applied to the second associated terminals of all rows in the block, and a negative voltage in the range of −1 volts to −5 volts is applied to the first associated terminals of all rows in the block. The first and second associated terminals of all columns in the block are supplied with zero volt.

To erase a block of the memory array using hot hole injection, a negative voltage in the range of, e.g., −1 volt to −3 volts is applied to the second associated terminals of all rows in the block, and 0 volt is applied to the first associated terminals of all rows in the block. The first associated terminals of all columns in the block are supplied with a relatively high positive voltage, in the range of, e.g., 6 volts to 10 volts, and the second associated terminals of all columns in the block are supplied with a voltage in the range of, e.g., 2 to 3 volts.

To program a non-volatile memory device in the memory array using tunneling, a relatively high programming voltage in the range of, e.g., 6 to 14 volts is applied to the second associated terminal, and approximately zero volt is applied to the first associated terminal of the row in which the non-volatile memory device is disposed. Also, a voltage in the range of, e.g., zero to 1 volt is applied to the first associated terminal, and a voltage in the range of, e.g., 2 to 5 volts is applied to the second associated terminal of the column in which the non-volatile device is disposed.

To program a non-volatile memory device in the memory array using hot electron injection, a relatively high programming voltage in the range of, e.g., 6 to 14 volts is applied to the second associated terminal and a voltage in the range of, e.g., 0.8 to supply voltage Vcc (e.g., 3.5) volts is applied to the first associated terminal of the row in which the non-volatile memory device is disposed. Also, a voltage in the range of, e.g., 3 to 6 volts is applied to the first associated terminal of the column in which the non-volatile device is disposed.

To read a non-volatile memory device in the memory array, a voltage in the range of, e.g., Vcc/2 to Vcc is applied to second associated terminal, and a voltage of, e.g., Vcc volt is applied to the first associated terminal of the array in which the non-volatile memory device is disposed. Also, a voltage in the range of, e.g., 1 to 2 volts is applied to the first associated terminal of the column in which the non-volatile memory device is disposed.

The accompanying drawings, which are incorporated in and form part of the specification, illustrate embodiments of the invention and, together with the description, serve to explain the principles of the invention.

### BRIEF DESCRIPTION OF THE DRAWINGS

FIG. 1 is a simplified transistor schematic diagram of a non-volatile DRAM, as known in the prior art.

FIG. 2 is a simplified transistor schematic diagram of a non-volatile SRAM, as known in the prior art.

FIG. 3 is a cross-sectional view of a non-volatile memory device, in accordance with one embodiment of the present invention.

FIG. 4 is a cross-sectional view of a second embodiment of a non-volatile memory device, in accordance with another embodiment of the present invention.

FIG. 5 is an exemplary array of non-volatile memory devices, in accordance with a first embodiment of the present invention.

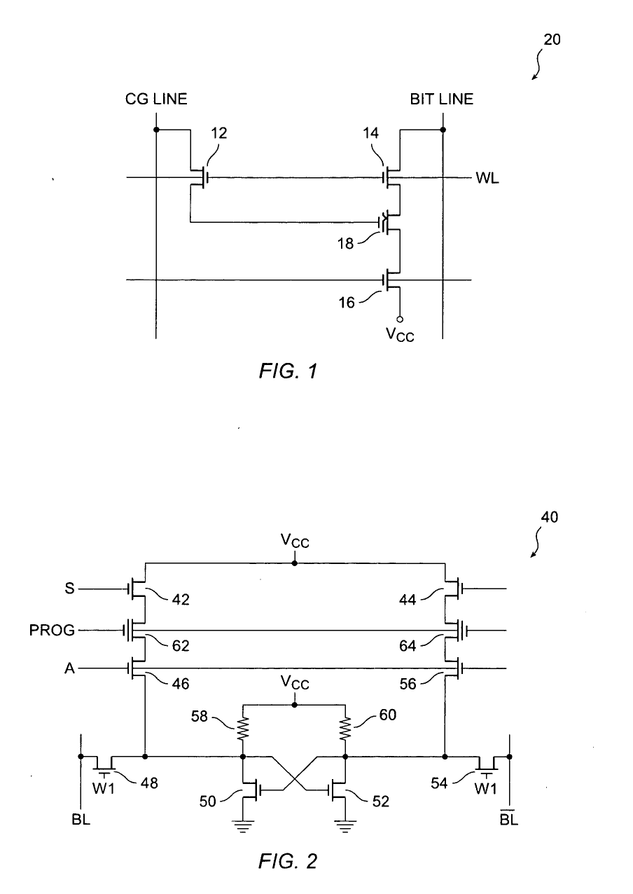

### DETAILED DESCRIPTION OF THE INVENTION

According to the present invention, a memory array formed using improved non-volatile memory device is provided. Although the invention has been applied to a single integrated circuit device in a memory application, there can be other alternatives, variations, and modifications. For example, the invention can be applied to embedded memory applications, including those with logic or microcircuits, and the like.

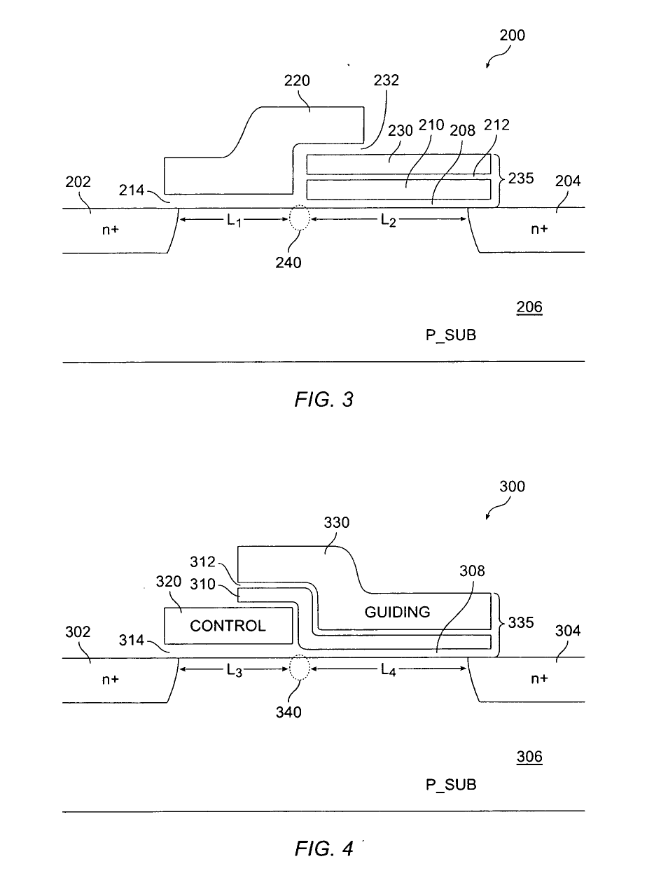

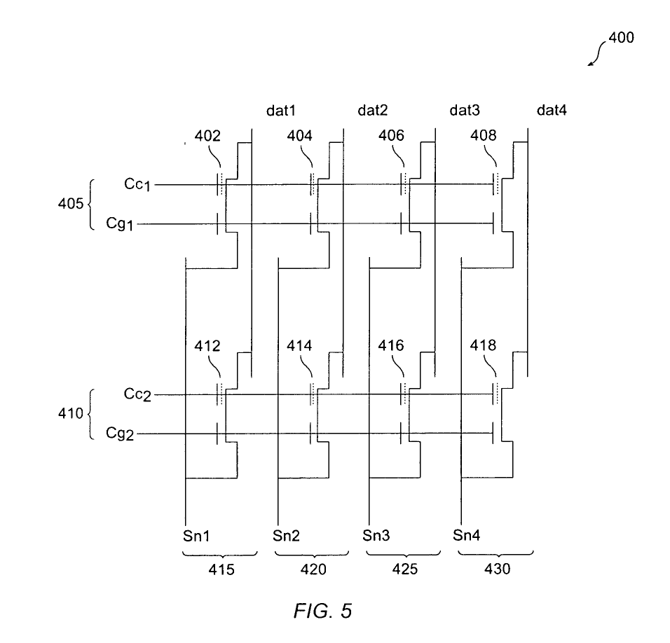

FIG. 3 is a cross-sectional view of non-volatile memory device 200 (hereinafter alternatively referred to as device 200) used to form a memory array, such as memory array 400 shown in FIG. 5, in accordance with one embodiment of the present invention. Device 200 includes, in part, a guiding gate 220, a control gate 230, n-type source region 202, n-type drain region 204, and p-type substrate region 206. Control gate 230, which is typically formed from polysilicon, is separated from substrate layer 206 via oxide layer 208, nitride layer 210 and oxide layer 212. In the following, control gate 230 together with oxide layer 208, nitride layer 210 and oxide layer 212 are collectively referred to in the alternative as MNOS gate 235. Guiding gate 220, which is also typically formed from polysilicon, is separated from substrate 206 via layer 214. Layer 214 may be an oxide layer or oxinitride layer or any other dielectric layer. Guiding gate 220 partially extends over control gate 230 and is separated therefrom via layer 232. Layer 232 may be an oxide layer, or a nitride layer, or a combination of oxide and nitride layers.

In some embodiments, oxide layer 208 has a thickness ranging from 20 Å to 60 Å, and each of nitride layer 210 and oxide layer 212 has a thickness ranging from 30 Å to 100 Å (FIG. 3 is not drawn to scale). In these embodiments, a first portion of channel length defined between the right vertical edge of source region 202 and the right vertical edge of guiding gate 220 that is positioned above gate oxide layer 214—shown as distance L₁—is equal to or longer than the minimum distance allowed by the manufacturing technology. For example, if device 200 is manufactured using 0.18μ CMOS technology, distance L₁ may also be approximately 0.18μ; if device 200 is manufactured using 0.09μ CMOS technology, distance L₁ may also be approximately 0.09μ.

Furthermore, in these embodiments, a second portion of channel length defined between the left vertical edge of drain region 204 and the left vertical edge of nitride layer 210 that is positioned above gate oxide layer 208—shown as distance L₂—is less than or equal to the minimum distance allowed by the manufacturing technology. For example, if device 200 is manufactured using 0.18μ CMOS technology, distance L₂ may vary from, e.g., approximately 0.06μ to approximately 0.18μ; if device 200 is manufactured using 0.25μ CMOS technology, distance L₂ may vary from, e.g., approximately 0.08μ to approximately 0.25μ.

Oxide layer 214 also has a thickness defined by the technology used to manufacture cell 200. For example, oxide layer 214 may have a thickness of 70 Å if 0.35μ CMOS technology is used to manufacture device 200. Similarly, oxide layer 214 may have a thickness of 50 Å if 0.25μ CMOS technology is used to manufacture device 200; oxide layer 214 may have a thickness of 40 Å if 0.18μ CMOS technology is used to manufacture device 200; oxide layer 214 may have a thickness of 20 Å if 0.09μ CMOS technology is used to manufacture device 200. Although the above exemplary embodiment of device 200 is described as being of n-channel type, it is understood that device 200 may be of p-channel type.

FIG. 4 is a cross-sectional view of non-volatile memory device 300 (hereinafter alternatively referred to as device 300) used to form a memory array, such as memory array 400 shown in FIG. 5, in accordance with another embodiment of the present invention. Device 300 includes, in part, a guiding gate 320, a control gate 330, n-type source region 302, n-type drain region 304, and p-type substrate region 306. Control gate 330, which is typically formed from polysilicon, is separated from substrate layer 306 via oxide layer 308, nitride layer 310 and oxide layer 312. In the following, control gate 330 together with oxide layer 308, nitride layer 310 and oxide layer 312 are collectively referred to in the alternative as MNOS gate 335. Guiding gate 320, which is also typically formed from polysilicon, is separated from substrate 306 via oxide layer 314. Guiding gate 320 partially extends under control gate 330 and is separated therefrom via oxide layer 308, nitride layer 310 and oxide layer 312.

In some embodiments, oxide layer 308 has a thickness ranging from 20 Å to 50 Å, and each of nitride layer 310 and oxide layer 312 has a thickness ranging from 30 Å to 100 Å (FIG. 4 is not drawn to scale). In these embodiments, a first portion of channel length defined between the right vertical edge of source region 302 and the right vertical edge of guiding gate 320 that is positioned above gate oxide layer 314—shown as distance L₃—is equal to or longer than the minimum distance allowed by the manufacturing technology. For example, if device 300 is manufactured using 0.18μ CMOS technology, distance L₃ may also be approximately 0.18μ; if device 300 is manufactured using 0.25μ CMOS technology, distance L₃ may also be approximately 0.25μ.

Furthermore, in these embodiments, a second portion of channel length defined between the left vertical edge of drain region 304 and the left vertical edge of nitride layer 310 that is positioned above gate oxide layer 308—shown as distance L₄—is less than or equal to the minimum distance allowed by the manufacturing technology. For example, if device 300 is manufactured using 0.18μ CMOS technology, distance L₄ may vary from, e.g., approximately 0.06μ to approximately 0.18μ; if device 300 is manufactured using 0.25μ CMOS technology, distance L₄ may vary from, e.g., approximately 0.08μ to approximately 0.25μ.

Oxide layer 314 also has a thickness defined by the technology used to manufacture device 300. For example, oxide layer 314 may have a thickness of 70 Å if 0.35μ CMOS technology is used to manufacture device 300. Similarly, oxide layer 314 may have a thickness of 50 Å if 0.25μ CMOS technology is used to manufacture device 300; oxide layer 314 may have a thickness of 40 Å if 0.18μ CMOS technology is used to manufacture device 300. Although the above exemplary embodiment of device 300 is described as being of n-channel type, it is understood that device 300 may be of p-channel type.

FIG. 5 shows an exemplary memory array 400 formed using the non-volatile memory devices described above, in accordance with one embodiment of the present invention. Array 400 is shown as including two rows, namely row 405, and 410, and four columns, namely columns 415, 420, 425, and 430. It is understood, however that memory array 400 may include more rows and columns, e.g., 1024 rows and 512 columns.

Disposed within array 400 are eight non-volatile memory devices 402, 404, 406, 408, 412, 414, 416, and 418. Each of these non-volatile memory devices may be the same as the non-volatile memory device 200, shown in FIG. 3, or the non-volatile memory device 300, shown in FIG. 4. Each of non-volatile memory devices 402, 404, 406, 408, 412, 414, 416, and 418 is alternatively referred to hereinbelow as a non-volatile memory cell.

As shown in FIG. 5, the guiding gate of each non-volatile memory cell disposed in row 405 is coupled to terminal Cg1, and the control gate of each non-volatile memory cell disposed in row 405 is coupled to terminal Cc1. Similarly, the guiding gate of each non-volatile memory cell disposed in row 410 is coupled to terminal Cg2, and the control gate of each non-volatile memory cell disposed in row 410 is coupled to terminal Cc2.

The drain terminals of non-volatile memory cells 402 and 412, disposed in column 415, are coupled to terminal dat1. The source terminals of non-volatile memory cells 402 and 412 are coupled to terminal Sn1. The drain terminals of non-volatile memory cells 404 and 414, disposed in column 420, are coupled to terminal dat2. The source terminals of non-volatile memory cells 404 and 414 are coupled to terminal Sn2. The drain terminals of non-volatile memory cells 406 and 416, disposed in column 425, are coupled to terminal dat3. The source terminals of non-volatile memory cells 406 and 416 are coupled to terminal Sn3. The drain terminals of non-volatile memory cells 408 and 418, disposed in column 430, are coupled to terminal dat4. The source terminals of non-volatile memory cells 408 and 418 are coupled to terminal Sn4. In some embodiments, terminals Snl, Sn2, Sn3, and Sn4 may be connected to each other.

In the following, the erase, programming and erase operations of array 400 are described below assuming that the non-volatile memory cells disposed in array 400 have n-channels. It is understood that to operate a memory array formed using p-channel non-volatile memory cells, in accordance with the present invention, the polarity of the voltages described below are reversed. In the following erase and programming operations using both hot-injection as well as tunneling are described. Moreover, in the following exemplary embodiments, where applicable, it is assumed that memory array 400 is manufactured using a 0.25 μm CMOS technology and that the Vcc supply voltage is about 3 volts.

Erase Operation Using Tunneling

The erase operation is done at a block level, with each block containing a number of rows, e.g., 32 to 256 rows, and a number columns, e.g., 8 to 128 columns. It is understood that a block may contain fewer or more rows and columns. For example, in some embodiments, a block may contain a single row of, e.g., 32 columns. It is assumed that rows 405, 410, and columns 402, 404, 406, and 408 are disposed in the same block. Therefore, following the erase operation, all the non-volatile memory cells in array 400 are erased. To erase a block using tunneling, a relatively high negative Vpp voltage, in the range of, e.g., −5 volts to −14 volts, is applied to terminals Ccl and Cc2, and a negative voltage in the range of, e.g., −1 to −5 volts is applied to terminals Cg1 and Cg2. To erase, each of terminals dat1, dat2, dat3, and dat4 is supplied with zero volt, and the substrate terminal (not shown) of each non-volatile memory cell in the block is also supplied with zero volt. To erase, terminals Sn1, Sn2, Sn3, and Sn4 may be supplied with zero volt or may be caused to float.

Referring to FIG. 3, the application of these voltages causes the electrons trapped in nitride layer 210 to tunnel through the oxide layer—due to Fowler-Nordheim tunneling—and return to substrate 206 and/or holes to tunnel through the oxide layer overlaying substrate 206 and be trapped in nitride layer 210 due to cold hole injection so as to neutralize the trapped electrons. The tunneling of trapped electrons back to substrate 206 and/or trapping of cold holes in nitride layer 210 causes the programmed non-volatile memory cell to erase. The erase operation causes the threshold voltage of the non-volatile memory cells disposed in the erased block to return to their pre-programming values.

Erase Operation Using Hot Hole Injection

A second way to erase the non-volatile memory cells disposed in array 400 is by hot hole injection. To cause hot hole injection, a negative voltage in the range of, e.g., −1 to −3 volts is applied to terminals Cc1 and Cc2. Terminals Cg1 and Cg2 are supplied with zero volts. Each of terminals datl, dat2, dat3, and dat4 is supplied with a relatively high positive Vpp voltage, in the range of, e.g., 6 volts to 10 volts, and the substrate terminal of each non-volatile memory cell in the block is also supplied with zero volt. Terminals Sn1, Sn2, Sn3, and Sn4 are supplied with a voltage in the range of, e.g., 1 to 3 volts.

Referring to FIG. 3, the application of these voltages causes a strong depletion region to form between drain region 204 and substrate region 206 of each non-volatile memory cell. This depletion region causes a relatively narrow region having a high electric field across it. Therefore, band-to-band tunneling takes place causing electrons to tunnel from the surface valence band toward the conduction band, thereby generating holes. The holes so generated drift toward the substrate. Some of these holes gain sufficient energy to inject through the oxide and be trapped in the nitride layer. The injected holes neutralize any electrons that are trapped in the nitride layer, thereby causing the threshold voltage of each non-volatile memory cell disposed in the erased block to return to its pre-programming value.

Programming Operation Using Tunneling

Assume it is desired to program non-volatile memory cell 404 of array 400 using tunneling. To achieve this, a relatively high programming voltage Vpp in the range of, e.g., 6 to 14 volts is applied to terminal Cc1, and approximately zero volt is applied to terminal Cg1. Also, a voltage of approximately zero volt is applied to the substrate terminal of non-volatile memory cell 404. To ensure that non-volatile memory cell 404 is programmed and non-volatile memory cells 402, 406 and 408 are not programmed, a voltage in the range of, e.g., 0 to 1 volt is applied to terminal dat2, and a voltage in the range of, e.g., 2 to 5 volts is applied to terminals dat1, dat3 and dat4.

Referring to FIGS. 3 and 4, the application of these voltages causes n-type channel regions of approximate lengths L₂ to be formed in substrate 206 of non-volatile memory cells 404. Due to the established electric filed (not shown), the electrons tunnel through the oxide layer overlaying substrate 206 of non-volatile memory cell 404 and are trapped in nitride layer 210 of non-volatile memory cell 404. The tunneled electrons remain trapped in nitride layer 210 of non-volatile memory cell 404 even after power is turned off. The trapped electrons, in turn, increase the threshold voltage of non-volatile memory cell 404 causing it to be programmed. Non-volatile memory cells 402, 406, and 408 are not affected by the application of these voltages Terminals. During the tunneling operation, terminals Cg2 and Cc2 are maintained at ground voltage.

Programming Operation Uing Hot Electron Injection

Assume it is desired to program non-volatile memory cell 404 of array 400 using hot electron injection. To achieve this, a relatively high programming voltage Vpp in the range of, e.g., 6 to 14 volts is applied to terminal Ccl, and a voltage in the range of, e.g., 0.8 to Vcc volts, is applied to terminal Cg1. Also, a voltage of approximately zero volt is applied to the substrate terminal of non-volatile memory cell 404. To ensure that non-volatile memory cell 404 is programmed and non-volatile memory cells 402, 406 and 408 are not programmed, a voltage in the range of, e.g., 3 to 6 volts is applied to terminal dat2, and a voltage in the range of, e.g., 0 to 1 volt is applied to terminals dat1, dat3 and dat4.

Referring to FIG. 3 and 4, the application of these voltages causes n-type channel regions of approximate lengths L₁ and L₂ to be formed in substrate 206 of non-volatile memory cell 404. The relatively high electric field in region 240 of substrate 206 is so adapted as to cause the hot electrons generated from the electron current that flow from source 202 of non-volatile memory cell 404 to drain 204 of non-volatile memory cell 404 to be injected into the nitride. The injected electrons remain trapped in nitride layer 210 of non-volatile memory cell 404 even after power is turned off. The trapped electrons, in turn, increase the threshold voltage of non-volatile memory cell 204. Non-volatile memory cells 402, 406, and 408 are not affected by the application of these voltages. During hot electron injection, terminals Cc2 and Cg2 are maintained at ground potential.

Read Operation

Assume it is desired to read the data stored in non-volatile memory cell 404. To achieve this, a voltage in the range of, e.g., Vcc/2 to Vcc is applied to terminal Cc1, and a voltage of, e.g., Vcc is applied to terminal Cg1. The substrate terminal of non-volatile memory cell 404 is supplied with zero volt, and a voltage in the range of, e.g. 1 to 2 volts is applied to terminal dat2. The application of these voltages causes a current to flow between terminals dat2 and sn2 (i.e., source 202 to drain 204 of non-volatile memory cell 404). As is known by those skilled in the art, if non-volatile memory cell 404 is programmed, due to its increased threshold voltage, a relatively small amount or no current flows between terminals dat2 and sn2. If non-volatile memory cell 404 is not programmed or erased, a relatively larger amount of current flows between terminals dat2 and sn2. A sense amplifier (not shown) senses the current that flows from between terminals dat2 and sn2 and by sensing the size of this current determines whether non-volatile memory cell 404 is programmed or not.

The above embodiments of the present invention are illustrative and not limitative. The invention is not limited by the type of integrated circuit in which the memory array of the present invention is disposed. For example, the memory array, in accordance with the present invention, may be disposed in a programmable logic device, a central processing unit, and a memory having arrays of memory cells or any other IC which is adapted to store data.

While the invention is described in conjunction with the preferred embodiments, this description is not intended in any way as a limitation to the scope of the invention. Modifications, changes, and variations, which are apparent to those skilled in the art, can be made in the arrangement, operation and details of construction of the invention disclosed herein without departing from the spirit and scope of the invention.

1. A non-volatile memory comprising:
N×M non-volatile memory devices disposed in an array having N rows and M columns, each non-volatile memory device further comprising:
a substrate region;
a source region formed in the substrate region;
a drain region formed in the substrate region and separated from the source region by a channel region;
a first gate overlaying a first portion of the channel and separated therefrom via a first insulating layer; and
a second gate overlaying a second portion of the channel and separated therefrom via a second insulating layer; wherein said first portion of the channel and said second portion of the channel do not overlap,
wherein each row of the array has a first associated terminal coupled to the first gates of the non-volatile devices disposed in that row, and a second associated terminal coupled to the second gates of the non-volatile devices disposed in that row, wherein each column of the array has a first associated terminal coupled to the drain regions of the non-volatile devices disposed in that column, and a second associated terminal coupled to the source regions of the non-volatile devices disposed in that column.

2. The non-volatile memory of claim 1 wherein to erase the non-volatile device disposed in row R, and column C of the M×N array, a relatively high first negative voltage is applied to the first terminal associated with row R, a second negative voltage greater than the first negative voltage is applied to the second terminal associated with row R, and a third voltage is applied to the first terminal associated with column C.

3. The non-volatile memory of claim 2 wherein the second terminal associated with column C is supplied with the third voltage.

4. The non-volatile memory of claim 2 wherein the second terminal associated with column C is caused to float.

5. The non-volatile memory of claim 1 wherein to erase the non-volatile device disposed in row R, and column C of the M×N array, a first negative voltage is applied to the first terminal associated with row R, a second voltage greater than the first negative voltage is applied to the second terminal associated with row R, a relatively high third positive voltage is applied to the first terminal associated with column C, and a fourth voltage less than the third positive voltage is applied to the second terminal associated with column C.

6. The non-volatile memory of claim 1 wherein to program the non-volatile device disposed in row R, and column C of the M×N array, a first relatively high positive voltage is applied to the second terminal associated with row R, a second voltage less than the first voltage is applied to the first terminal associated with row R and to the second terminal associated with column C, and a third voltage greater than or equal to the second voltage is applied to the first terminal associated with column C.

7. The non-volatile memory of claim 1 wherein to program the non-volatile device disposed in row R, and column C of the M×N array, a first relatively high positive voltage is applied to the first terminal associated with row R, a second positive voltage greater than the first voltage is applied to the second terminal associated with row R, a third voltage less than the second voltage is applied to the first terminal associated with column C, and a fourth voltage less than the third voltage and smaller than the first voltage is applied to the second terminal associated with column C.

8. The non-volatile memory of claim 1 wherein to read the non-volatile device disposed in row R, and column C of the M×N array, a first positive supply voltage is applied to the first terminal associated with row R, a second voltage in the range of one-half to the positive supply voltage is applied to the second terminal associated with row R, and a third voltage in the range of one-third of the supply voltage to two-third of the supply voltage is applied first terminal associated with column C.

9. The non-volatile memory of claim 1 wherein in each non-volatile memory device, said first insulating layer is an oxide layer.

10. The non-volatile memory of claim 9 wherein for each non-volatile memory device, said second insulating layer further comprises a first oxide layer formed over said channel region, a first nitride layer formed over said first oxide layer of the second insulating region, and a second oxide layer formed over said first nitride layer.

11. The non-volatile memory of claim 10 wherein for each non-volatile memory device, said first oxide layer of the first insulating layer is thinner than the first oxide layer of the second insulating layer.

12. The non-volatile memory of claim 10 wherein for each non-volatile memory device, said first oxide layer of the first insulating layer is thicker than the first oxide layer of the second insulating layer.

13. The non-volatile memory of claim 11 wherein for each non-volatile memory device, said first gate extends partially over the second gate.

14. The non-volatile memory of claim 12 wherein for each non-volatile memory device, said second gate extends partially over the first gate.

15. The non-volatile memory of 6 wherein a channel connecting the source region to the drain region is formed in the substrate region of the non-volatile memory device being programmed.

16. The non-volatile memory of claim 1 wherein said substrate region is a p-type region formed in a n-well region.
